(19) United States
(12) Patent Application Publication
(10) Pub. No.: US 2025/0328173 A1
(43) Pub. Date: Oct. 23, 2025

(54) APPARATUS, SYSTEMS, AND METHODS FOR AIRFLOW MANAGEMENT IN CHASSIS FOR ELECTRONIC DEVICES

(71) Applicants: Hamid MohammadMirzaieDaryan, Toronto (CA); Jain Raj Vettuvazhy Puthenpurayil, Bengaluru (IN); Ali Kalantarian, Richmond Hill (CA)

(72) Inventors: Hamid MohammadMirzaieDaryan, Toronto (CA); Jain Raj Vettuvazhy Puthenpurayil, Bengaluru (IN); Ali Kalantarian, Richmond Hill (CA)

(21) Appl. No.: 19/258,613

(22) Filed: Jul. 2, 2025

(51) Int. Cl. G06F 1/20; H05K 7/20

(52) U.S. Cl. CPC G06F 1/20; H05K 7/20145; H05K 7/20172

(57) ABSTRACT

Apparatus, systems, and methods for airflow management in chassis for electronic devices are disclosed. An example apparatus includes a shroud having an inlet defined in a first surface, an intake vent defined in a second surface, and an outlet defined in a third surface; a backplate coupled to the shroud to form a housing; and a blower in the housing, the blower to receive air via the inlet and the intake vent and to direct the air toward the outlet.

### BACKGROUND

A chassis of a compute device houses multiple electronic components within a volume of the chassis, such as a central processing unit, a graphics processing unit, memory devices, etc. The electronic components output heat in the chassis during operation of the compute device.

### BRIEF DESCRIPTION OF THE DRAWINGS

FIG. 1 illustrates an example chassis in which examples disclosed herein may be implemented.

FIG. 2 is a cutaway view of the example chassis and illustrates an example housing for an electronic component, the housing including a shroud having an auxiliary intake vent in accordance with teachings of this disclosure.

FIG. 3 illustrates the example housing of FIG. 2.

FIG. 4 is a cutaway view of the example housing of FIG. 2 illustrating electronic components therein.

FIG. 5 is another cutaway view of the example housing of FIG. 2.

FIG. 6 is a flowchart of an example method of creating a shroud having an auxiliary intake vent in accordance with teachings of this disclosure.

FIG. 7 is a flowchart of an example method of assembling a chassis including the example housing of FIGS. 2-5 in accordance with teachings of this disclosure.

In general, the same reference numbers will be used throughout the drawing(s) and accompanying written description to refer to the same or like parts. The figures are not necessarily to scale.

### DETAILED DESCRIPTION

A chassis of a compute device houses electronic components within a volume of the chassis, such as a central processing unit (CPU), a graphics card including a graphics processing unit (GPU), memory devices, etc. A chassis including the hardware components therein can define a workstation that can be operably coupled to, for instance, a display. Electronic components in the chassis, such as a GPU, output heat during performance of workloads. Performance of the electronic component(s) is dependent on airflow within the chassis to dissipate heat. Without sufficient airflow to dissipate heat, the performance of the electronic component(s) can be adversely affected. For example, excess heat can cause a GPU to implement thermal throttling to prevent overheating, which reduces performance of the GPU and compromises stability of the compute system.

Some chassis are designed to have a minimal or compact form factor to reduce space occupied by the chassis. However, as a size of the chassis decreases, a volume of the chassis decreases in size such that the electronic components are in closer proximity to each other in the chassis and/or in closer proximity to walls of the chassis as compared to larger chassis. As a result, a compact chassis form factor can introduce spatial limitations that can affect (e.g., impede) efficient airflow within a chassis for cooling purposes.

Although increasing rotational speeds of fan(s) in the chassis can provide for increased airflow within the chassis, increased fan speeds also increase noise generated by the fan(s). Increased noise can contribute to a negative user experience and/or fail to meet industry acoustic standards. Thus, efforts to manage thermal performance should be balanced in view of acoustic constraints.

Disclosed herein are example systems, apparatus, and methods that provide for airflow paths that improve thermal performance of electronic component(s) in a chassis without compromising acoustic performance. Examples disclosed herein include a cover or a shroud for an electronic component such as a graphics card that provides for additional airflow via an auxiliary intake vent defined in the shroud. In examples disclosed herein, the intake vent is auxiliary to, for example, other inlet(s) defined in the shroud, or intake vent(s) defined in a backplate that is coupled to the shroud. In some examples, the hardware component includes a blower or fan in an interior of the shroud for cooling electronic components via circulation of air. In such examples, the auxiliary intake vent provides an additional air intake flow path for the blower or fan. As a result, airflow in a housing of the hardware component (where the housing is defined by the shroud and the backplate coupled thereto) is increased, which facilitates cooling of the electronic component(s) in the housing while maintaining or not otherwise increasing noise output by the blower or fan.

Example shrouds disclosed herein including auxiliary intake vents can be oriented in the chassis so that a temperature of the air entering the auxiliary intake vent is reduced. For example, the housing can be oriented in the chassis such that the auxiliary intake vent is proximate to an exterior vent (e.g., grille) of the chassis. For example, a portion of the shroud including the auxiliary intake vent can face the exterior vent, can be located closer to the exterior chassis vent than a portion of the shroud that includes an outlet, etc. As a result, low-temperature ambient air flowing into the chassis via the exterior grille is drawn into the auxiliary intake vent before the air circulates elsewhere within the chassis and absorbs heat from other electronic components in the chassis. Therefore, air entering the auxiliary intake vent has a lower intake temperature, which further facilitates dissipation of heat from the electronic component(s) (e.g., a GPU package) and, in some examples, surrounding components in the chassis, while meeting acoustic performance criteria.

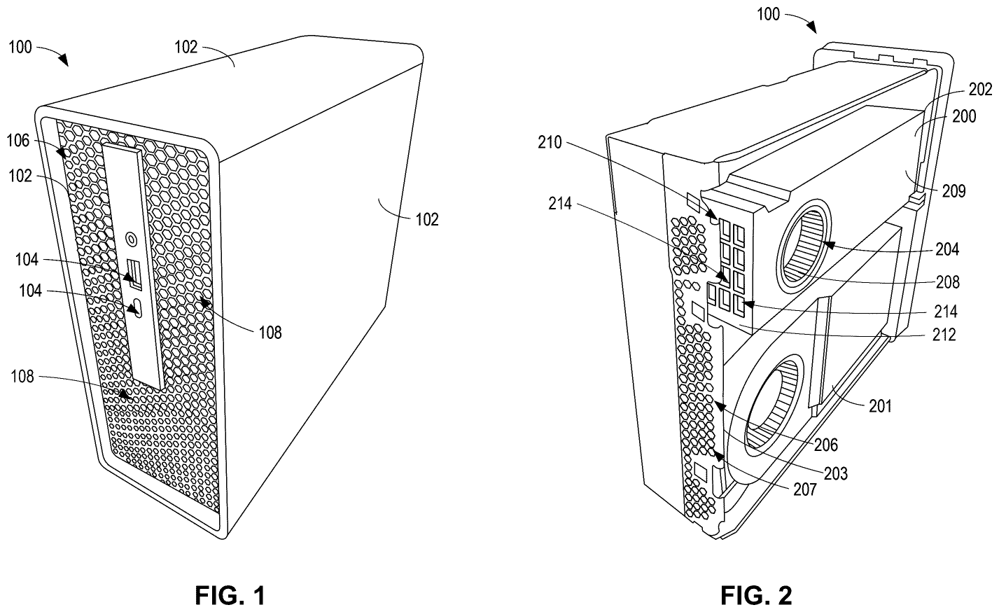

FIG. 1 illustrates an example chassis 100 in which examples disclosed herein may be implemented. The chassis 100 is formed by walls 102 that define a volume to house electronic components of, for example, a personal compute device. In some examples, the chassis 100 and hardware therein define a desktop workstation that operatively couples to a display via one or more ports 104 of the chassis 100.

The chassis 100 of FIG. 1 includes an exterior grille 106 (e.g., a vent) having openings 108 to allow air to flow into the internal space of the chassis 100 to cool the electronic components therein. In the example of FIG. 1, the exterior grille 106 substantially defines a sidewall 102 of the chassis 100 and, in particular, forms an exterior surface of the chassis 100. However, the exterior grille 106 can have a different size and/or location relative to the chassis 100 than shown in FIG. 1. Also, a size and/or of the openings 108 of the exterior grille 106 can differ from those shown in FIG. 1.

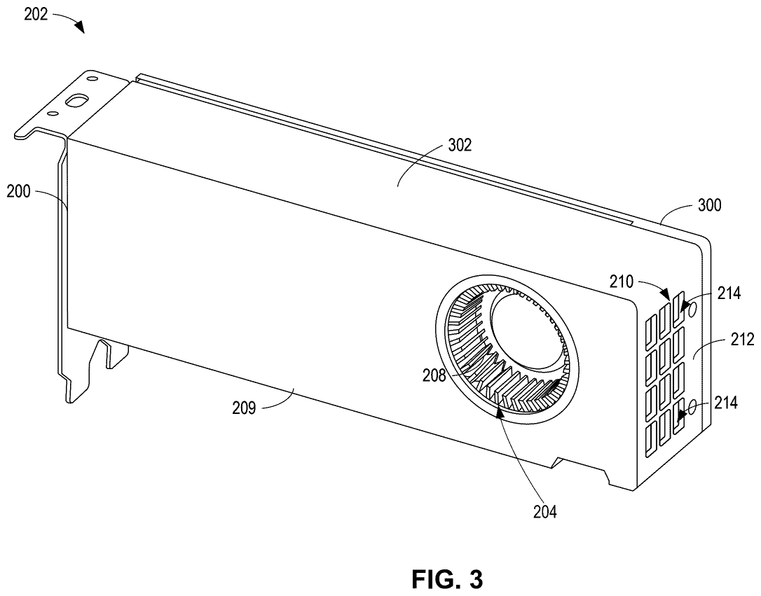

FIG. 2 is a cutaway view of the example chassis 100 of FIG. 1 and, in particular, illustrates housings of electronic components carried by the chassis 100. For example, the chassis 100 carries a graphics card, where the graphics card is covered by a shroud 200. As disclosed herein, the shroud 200 and a backplate (FIG. 3) that is coupled to the shroud 200 form a housing 202 of the graphics card (e.g., to support electronic components of the graphics card such as a graphics processing unit (GPU), memory devices, etc.). The chassis 100 also carries a central processing unit (CPU) covered by a shroud 201. The shrouds 200, 201 can be made of, for example, a plastic material.

In the example of FIG. 2, the shrouds 200, 201 are coupled to one or more platforms 203 in the interior of the chassis 100 to secure shrouds 200, 201. One of the platforms 203 is shown in FIG. 2. The platform 203 can have a different shape and/or size than shown in FIG. 2. In this example, the platform 203 has a second grille 206 including openings 207 defined in a portion of the platform 203 to enable air entering the chassis 100 via the exterior grille 106 to pass through the second grille 206 of the platform 203 for cooling of the electronic components in the chassis 100. The platform 203 can include other apertures, cutouts, notches, etc. to reduce (e.g., minimize) obstruction of the flow of air from the exterior grille 106 to the electronic components in the chassis 100. In some examples, the chassis 100 does not include the platform(s) 203 and, instead, the shrouds 200, 201 are coupled to inner surfaces of sidewalls 102 of the chassis 100 via, for example, brackets.

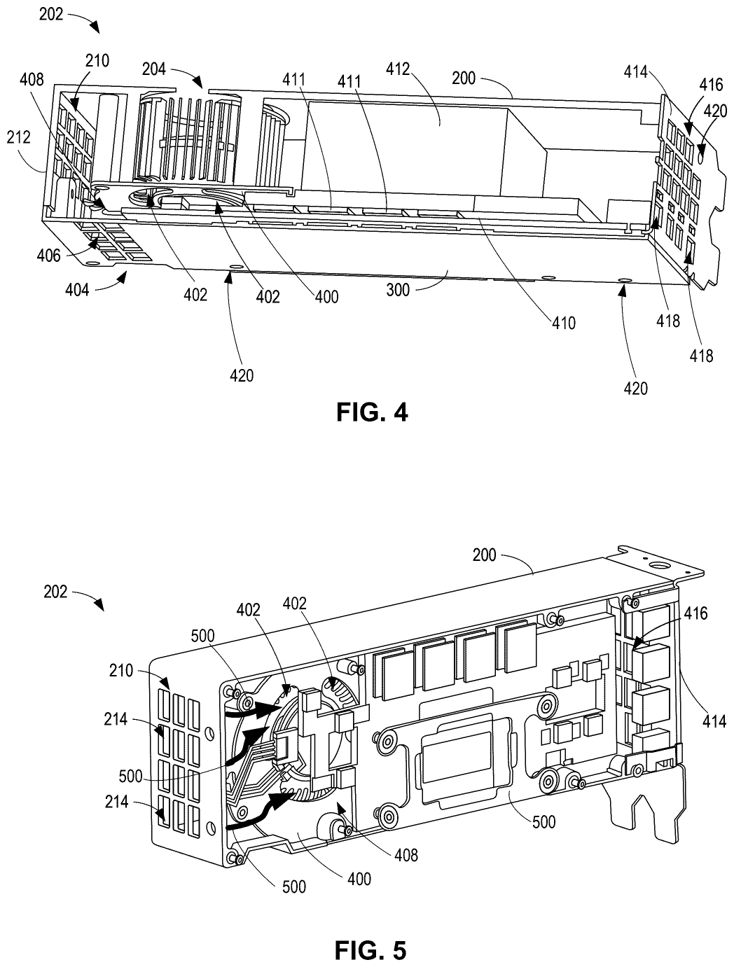

The shroud 200 of the graphics card will be discussed herein for illustrative purposes. The shroud 200 of the graphics card includes an inlet 204 (e.g., an aperture) defined in a first surface 209 of the shroud 200. The aperture 204 serves as an inlet for a blower 208 in the housing 202. As shown in FIG. 2, the blower 208 is positioned in the housing 202 such that the blower 208 is aligned (e.g., axially aligned) or substantially aligned with the inlet 204. Air passing through the inlet 204 is directed by the blower 208 toward, for example, a heat sink (FIG. 4) in the housing 202 to facilitate cooling of the electronic components of the graphics card. Although the example housing 202 of FIG. 2 carries the blower 208, in other examples, a fan can be carried by the housing 202 to cool the electronic components of the graphics card. A size and/or a shape of the inlet 204 can differ from the example of FIG. 2. Also, a location of the inlet 204 and, thus, the blower 208, relative to the shroud 200 can differ from the example of FIG. 2.

In the example chassis 100 of FIGS. 1 and 2, the inlet 204 of the shroud 200 faces one of the sidewalls 102 (FIG. 1) of the chassis 100. However, to reduce a form factor of the chassis 100, there is limited clearance between the chassis sidewall 102 and the shroud 200. Also, the backplate (FIG. 3) is coupled to a side of the shroud 200 opposite the side including the inlet 204. In the example chassis 100 of FIGS. 1 and 2, the backplate faces other electronic components in the chassis 100. In some examples, the backplate includes a vent (FIG. 4) defined therein to provide additional airflow to the blower 208. However, in view of the compact form factor of the chassis 100, there is also limited clearance between the backplate and the other electronic components in the chassis 100. Such spatial limitations may reduce airflow through the inlet 204 and/or the vent formed in the backplate. Further, air passing through the inlet 204 and/or the vent in the backplate (FIG. 4) is subject to heat dissipated by other components in the chassis 100 as well as heat radiated by the shroud 200 and/or the backplate. Thus, a temperature of the air can be elevated (i.e., preheated) prior to entering the inlet 204 and/or the vent in the backplate, which can reduce the cooling efficiency of the blower 208.

To provide additional airflow for the blower 208, the example shroud 200 of FIG. 2 includes an auxiliary intake vent 210 defined in a second surface 212 of the shroud 200. The auxiliary intake vent 210 includes openings 214. As shown in FIG. 2, the second surface 212 forms an end of the shroud 200. Also, in this example, the second surface is orthogonal to the first surface 209. The auxiliary intake vent 210 increases the amount of air to the blower 208 via fluid communication between the auxiliary intake vent 210 and the blower 208. Put another way, the auxiliary intake vent 210 provides for supplemental air to the blower 208 in addition to the air entering via the inlet 204 (and/or the air entering via a vent formed in the backplate (FIG. 4)). Thus, in the example of FIG. 2, the blower 208 receives air from more than one inlet (e.g., the inlet 204 and the auxiliary vent 210).

Also, in the example chassis 100 of FIGS. 1 and 2, the housing 202 is arranged in the chassis 100 such that the auxiliary intake vent 210 is proximate to the exterior grille 106 of the chassis 100. In this example, the second surface 212 that includes the auxiliary intake vent 210 faces the exterior grille 106. Thus, air flowing through the openings 108 of the exterior grille 106 (and the openings 207 of the second grille 206 of the platform 203) passes through the openings 214 of the auxiliary intake vent 210 toward the blower 208 with less flow resistance as compared to if, for instance, the auxiliary intake vent 210 was located on an opposite side of the shroud 200 from the second surface 212.

Because of the spatial proximity of the auxiliary intake vent 210 to the exterior grille 106 (FIG. 1), air entering the housing 202 via the auxiliary intake vent 210 has a lower temperature as compared to air that is drawn into the blower via the inlet 204, which is more likely to be subject to heat from other components prior to entering the inlet 204, as discussed above. Thus, because of the spatial proximity of the openings 108 of the exterior grille 106 and the openings 214 of the auxiliary intake vent 210, the auxiliary intake vent 210 facilitates a reduction in average air intake temperature in the chassis 100.

Although examples disclosed herein are primarily discussed with respect to the auxiliary intake vent 210 of the shroud 200 for the graphics card, the auxiliary intake vent 210 can be formed in other shrouds or covers for electronic components in the chassis 100. For example, the auxiliary intake vent 210 can be formed in the shroud 201 of the central processing unit on a surface of the shroud 201 proximate to the exterior grille 106 (e.g., facing the exterior grille 106). As another example, the auxiliary intake vent 210 can be formed in a shroud of a solid-state drive (SSD) in the chassis 100. Also, although examples disclosed herein refer to chassis having compact form factors, examples disclosed herein can be implemented in larger chassis.

FIG. 3 illustrates the example housing 202 of the graphics card of FIG. 2. As discussed above, the shroud 200 and the backplate 300 define the housing 202, which carries electronic components of the graphics card such as the GPU and memory devices. As shown in FIG. 3, the auxiliary intake vent 210 includes the openings 214. The openings 214 can have a different size or shape than shown in FIG. 3. In some examples, a size of the openings 214 is selected to increase (e.g., maximize) air intake and reduce airflow resistance while complying with safety standards to prevent, for instance, a user from inserting his or her finger through the openings 214. The number of openings 214 of the auxiliary intake vent 210 can differ from the example of FIG. 3. Also, although in the example of FIG. 3 the blower inlet 204 and the openings 214 of the auxiliary intake vent 210 have different shapes, in some examples, the blower inlet 204 and the openings 214 of the auxiliary intake vent 210 have similar shapes (e.g., both circular).

In this example, the auxiliary intake vent 210 is formed in the second surface 212 of the shroud 200 proximate to the inlet 204 and, thus, the blower 208 to reduce (e.g., minimize) airflow resistance between the auxiliary intake vent 210 and the blower 208 and provide cooler (i.e., less preheated) air to the blower 208. However, the auxiliary intake vent 210 could be formed in, for example, a third surface 302 of the shroud 200 at a location proximate to the blower 208. In some examples, the second surface 212 and the third surface 302 can each include auxiliary intake vents 210 formed therein. The auxiliary intake vent(s) 210 are located on the shroud 200 such that the blower 208 intakes air passing through the auxiliary intake vent(s) 210 and directs the air toward an outlet (FIG. 4) formed in the housing 202. As the air flows toward the outlet (FIG. 4), the air absorbs heat dissipated by the electronic component(s) in the housing 202 to cool the electronic component(s). The location and/or number of the auxiliary intake vent(s) 210 can be selected based on the position of the blower 208 in the housing 202, a direction in the blower 208 direct the air toward the outlet, the side of the chassis 100 that includes the exterior grille 106, the workload capacity of the GPU, etc.

FIG. 4 is a cutaway view of the example housing 202 of FIGS. 2 and 3 in which the third surface 302 of the shroud 200 has been removed to illustrate components in the interior of the housing 202 of the graphics card. As shown in FIG. 4, a blower mount 400 (e.g., a platform or other surface) supports the blower 208 in the housing 202. In the example of FIG. 4, the blower mount 400 includes openings 402 defined therein. Also, in this example, the backplate 300 includes an intake vent 404 defined by openings 406. The backplate intake vent 404 of FIG. 4 is proximate to the blower 208. A size, shape, and/or number of the respective openings 402 of the blower mount 400 and/or the respective openings 406 of the backplate intake vent 404 can differ from the examples shown in FIG. 4. In some examples, a size of the openings 402 of the blower mount 400 are selected so that the size of the openings is increased (e.g., maximized) while still providing for sufficient structural support of the blower 208 by the blower mount 400. Also, to prevent reverse flow, an outer diameter or edge of the respective openings 406 is less than a diameter of the blower 208.

In the example of FIG. 4, a gap 408 is defined between the blower mount 400 and the backplate 300 such that air flows through the openings 406 of backplate intake vent 404 and through the openings 402 in the blower mount 400 to provide for airflow to the blower 208 in addition to the air intake via the inlet 204. A size of the gap 408 can be defined based on a summation of a first distance between components on the printed circuit board 410 and the blower mount 400 and a second distance between the printed circuit board 410 and the backplate 300 (where the first and second distances can be defined by industry safety standards). As disclosed herein, air passing through the auxiliary intake vent 210 also passes through the gap 408 for intake by the blower 208. Thus, the example blower 208 of FIG. 4 is a dual inlet blower (i.e., the inlet 204 in the shroud 200 and the inlets formed by the openings 402 in the blower mount 400). Further, in this example, the blower 208 is in fluid communication with three air intake sources, namely, the inlet 204, the backplate intake vent 404, and the auxiliary intake vent 210. However, in some examples, the backplate 300 does not include the backplate intake vent 404.

In addition to the blower 208, the housing 202 carries a printed circuit board 410 to support electronic components 411 such as a GPU, memory devices, etc. (where the PCB 410 and electronic components 411 coupled thereto form the graphics card). A heatsink 412 is located over the printed circuit board 410 to absorb heat output by the electronic components of the printed circuit board 410. The blower 208 directs air (e.g., via baffle(s)) in the direction of the heatsink 412 to facilitate removal of the heat. As shown in FIG. 4, the blower 208 and the second surface 212 including auxiliary intake vent 210 are on a first (i.e., same) side of the heatsink 412 such that cool air entering the auxiliary intake vent 210 is directed across the heatsink 412 via the blower 210.

A fourth surface 414 of the shroud 200 forms another end of the shroud 200 opposite the second surface 212 that includes the auxiliary intake vent 210. When the shroud 200 is in the chassis 100 of FIG. 1, the fourth surface 414 is distal from the exterior grille 106. The fourth surface 414 of the shroud 200 includes an outlet 416 defined by a plurality of openings 418. After the air is blown across the heatsink 412 (and absorbs the heat output by the electronic components 411), the air exits the housing 202 via the outlet 416. The outlet 416 is located on a second, opposite side of the heatsink 412 from the auxiliary intake vent 210 and the blower 208 (and from the other air intake sources such as the inlet 204 and that backplate vent 404). Put another way, when the housing 202 is in the chassis 100 of FIG. 1, the auxiliary vent 210 is in a portion of the shroud 200 that is closer to (e.g. proximate to) the exterior grille 106 of the chassis 100 than the portion of the shroud 200 including the outlet 416. Also, as shown in FIG. 4, one or more surfaces of the shroud 200 (e.g., the surface(s) 212, 414) and/or the backplate 300 can include opening(s) 420 defined therein to enable the housing 202 to be mounted to, for example, the platform(s) 203 (FIG. 2) and/or the sidewall(s) 102 of the chassis 100 via fastener(s), bracket(s), etc.

FIG. 5 is another cutaway view of the example housing 202 of FIGS. 2 and 3 in which the backplate 300 and the printed circuit board 410 have been removed for illustrative purposes. As shown in FIG. 5, air passes through the openings 214 of the auxiliary intake vent 210 toward the openings 402 in the blower mount 400 via the gap 408 for intake by the blower 208, as represented by the arrows 500 (i.e., flow paths) in FIG. 5. Thus, air intake by the blower 208 is increased via the auxiliary intake vent 210. In some examples, the auxiliary intake vent 210 can provide for a 10% increase in air intake at the shroud 200 as compared to shrouds that do not include the auxiliary intake vent 210. As disclosed herein, the air exits the housing 202 via the outlet 416 in the fourth surface 414 of the shroud 200 after flowing across the heatsink 412 (FIG. 4).

The gap 408 between the backplate 300 (FIG. 3) and the blower mount 400 provides for low resistance flow of the air entering the housing 202 via the auxiliary intake vent 210 of the shroud 200 and the backplate intake vent 404 (FIG. 4). Also, the resistance of air flowing into the housing 202 via the auxiliary intake vent 210 is reduced due to the proximity of the auxiliary intake vent 210 to the exterior grille 106 of the chassis 100. The low resistance flow path from the exterior grille 106 to the auxiliary intake vent 210 and from the auxiliary intake vent 210 to the blower 208 results in more low temperature air for the blower 208. The increased flow of lower temperature air results in more efficient cooling of the components (e.g., GPU, memory) of the graphics card in the housing 202. Therefore, the temperatures of the electronic components of the graphics card are reduced. Efficient cooling of the graphics card can facilitate performance improvements with respect to, for example, clock speed and total board power (TBP).

Further, the increased number of air inlets at the shroud 200 due to the auxiliary intake vent 210 provides for increased airflow without adversely affecting (e.g., increasing) acoustic noise generated by the blower 208. High resistance airflow and/or preheated air can increase the workload for the blower 208 to cool the graphics card as compared to low resistance, lower temperature airflow. As the workload on the blower 208 increases, the noise (e.g., sound pressure level (SPL), e.g., measured as dBA) generated by the blower 208 increases. Thus, the acoustic performance of the compute device is negatively impacted without substantial gains in cooling efficiency. Conversely, the increase in low resistance, lower temperature airflow provided via the auxiliary intake vent 210 enables the blower 208 to operate more efficiently while not raising the acoustic noise level and, in some examples, lowering acoustic noise output.

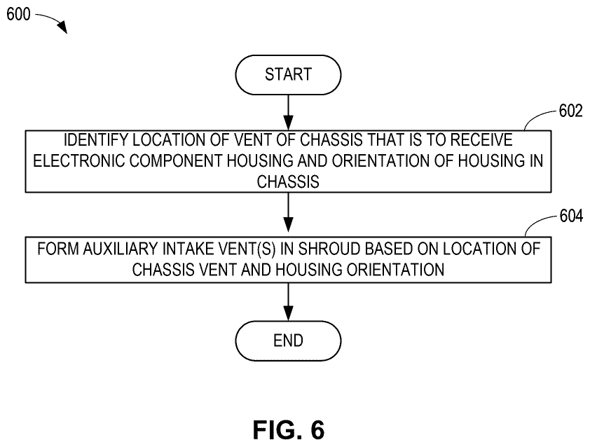

FIG. 6 is a flowchart of an example method 600 for creating a shroud having an auxiliary intake vent, such as the example shroud 200 of FIGS. 2-5. At block 602, the example method 600 includes identifying a location of an exterior vent or grille 106 of the chassis 100 that is to receive the housing 202 of an electronic component (e.g., a graphics card) and an orientation of the housing 202 in the chassis 100. For example, the particular chassis sidewall 102 that includes the exterior grille 106 can be identified.

At block 604, the example method 600 includes forming the auxiliary intake vent(s) 210 in the shroud 200. In this example, the formation of the auxiliary intake vent(s) 210 in the shroud 200 is based on the location of the exterior grille 106 and the orientation of the housing 202 in the chassis 100 so that the auxiliary intake vent(s) 210 are proximate the exterior grille 106 (e.g., facing the exterior grille 106, closer to the exterior grille 106 than a portion of the shroud including the outlet 416) to increase flow of low temperature air into the housing 202. The openings 214 of the auxiliary intake vent(s) 210 can be formed via manufacturing processes such as extrusion.

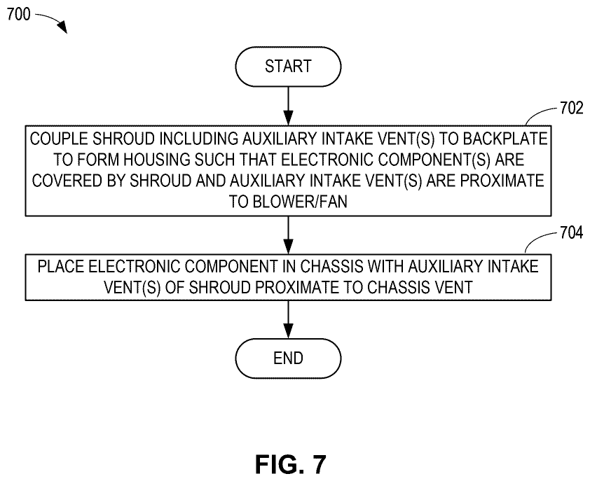

FIG. 7 is a flowchart of an example method 700 for providing increased airflow to electronic component(s) (e.g., a graphics card, a CPU, an SSD) in a chassis via an auxiliary intake vent in a shroud, such as the chassis 100 of FIG. 1 that carries the shroud 200 including the auxiliary intake vent 210 of FIGS. 2-5. At block 702, the example method 700 of FIG. 7 includes coupling the shroud 200 including the auxiliary intake vent(s) 210 to the backplate 300 to form the housing 202 such that the printed circuit board 410 and electronic components 411 (e.g., a GPU, memory) coupled thereto are covered by the shroud 200 and the auxiliary intake vent(s) 210 are proximate to the blower 208 (or, in some examples, a fan) to provide for low-resistance airflow path(s) between the auxiliary intake vent(s) 210 and the blower 208 (or fan) and to facilitate intake of cool air by the blower 208. At block 704, the example method 700 includes placing the electronic component housing 202 in the chassis 100 with the auxiliary intake vent(s) 210 proximate to (e.g., facing) the exterior vent or grille 106 of the chassis 100 to provide for an airflow path from the exterior grille 106 to the blower 208 via the auxiliary intake vent(s) 210 in the shroud 200. In some examples, the housing 202 is coupled to the platform 203 including the second grille 206 such that air can flow from the exterior grille 106 through the second grille 206 and into the housing 202.

While an example manner of providing increased airflow to an electronic component is illustrated in FIGS. 6 and/or 7, one or more of the elements, processes and/or devices illustrated in FIGS. 6 and/or 7 may be combined, divided, re-arranged, omitted, eliminated, and/or implemented in any other way.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

From the foregoing, it will be appreciated that example systems, apparatus, articles of manufacture, and methods have been disclosed that provide for increased air intake via a shroud of an electronic component (e.g., a graphics card, a CPU). Example shrouds disclosed herein include vent(s) to supplement, for example, a blower inlet defined the shroud and/or a vent defined in a backplate. As a result, example shrouds disclosed herein provide for increased air intake by the blower, thereby increasing cooling efficiency while maintaining low noise emissions to satisfy acoustic standards. Example shrouds disclosed herein can be arranged in a chassis to provide for low resistance flow of low temperature ambient air into the shroud for intake by the blower or fan. Thus, examples disclosed herein provide for efficient cooling in a spatially constrained environment such as a chassis having a small or compact form factor.

Example apparatus, systems, and methods for airflow management in chassis for electronic devices are disclosed. Further examples and combinations thereof include the following:

Example 1 includes an apparatus comprising a shroud having an inlet defined in a first surface, an intake vent defined in a second surface, and an outlet defined in a third surface; a backplate coupled to the shroud to form a housing; and a blower in the housing, the blower to receive air via the inlet and the intake vent and to direct the air toward the outlet.

Example 2 includes any preceding clause(s) of Example 1, further including a mount in the housing to support the blower, the mount including an opening defined therein, the opening in fluid communication with the intake vent.

Example 3 includes any preceding clause(s) of any one or more of Examples 1-2, wherein a gap is defined between the backplate and the mount, an airflow path defined from the intake vent to the blower via the gap.

Example 4 includes any preceding clause(s) of any one or more of Examples 1-3, wherein the intake vent is a first intake vent and the backplate includes a second intake vent defined therein.

Example 5 includes any preceding clause(s) of any one or more of Examples 1-4, wherein the intake vent includes a plurality of openings defined in the second surface of the shroud.

Example 6 includes any preceding clause(s) of any one or more of Examples 1-5, wherein the second surface is orthogonal to the first surface.

Example 7 includes any preceding clause(s) of any one or more of Examples 1-6, wherein the first surface is opposite the backplate.

Example 8 includes a system comprising a chassis having a grille defining an exterior surface thereof; an electronic component; a blower; and a housing in the chassis, the electronic component and the blower in housing, the housing including a shroud having an inlet for the blower and an intake vent; and a backplate coupled to the shroud, the backplate spaced apart from the blower to define a gap between the backplate and the blower, an airflow path to the blower defined by the grille, the intake vent, and the gap.

Example 9 includes any preceding clause(s) of Example 8, wherein a first surface of the shroud including the intake vent faces the grille of the chassis.

Example 10 includes any preceding clause(s) of any one or more of Examples 8-9, wherein a second surface of the shroud includes an outlet, the second surface opposite the first surface.

Example 11 includes any preceding clause(s) of any one or more of Examples 8-10, wherein the housing includes a mount to support the blower, the mount including an opening defined therein, the opening in fluid communication with the gap.

Example 12 includes any preceding clause(s) of any one or more of Examples 8-11, wherein the intake vent is a first intake vent and the backplate includes a second intake vent defined therein, air entering the second intake vent to pass through the gap toward the blower.

Example 13 includes any preceding clause(s) of any one or more of Examples 8-12, wherein the electronic component is a graphics processing unit.

Example 14 includes any preceding clause(s) of any one or more of Examples 8-13, wherein the electronic component is a central processing unit.

Example 15 includes a graphics card comprising a shroud, a first surface of the shroud having a first opening defined therein, a second surface of the shroud having a plurality of second openings defined therein; a graphics processing unit covered by the shroud; a blower covered by the shroud, the blower to intake air via the first opening and the plurality of second openings; and a backplate coupled to the shroud, the backplate opposite the first surface.

Example 16 includes any preceding clause(s) of Example 15, further including a heatsink covered by the shroud, the shroud including a third surface having a plurality of third openings defined therein, wherein the second surface and the blower are on a first side of the heatsink and the third surface is on a second side of the heatsink opposite the first side, the air to exit via the plurality of third openings.

Example 17 includes any preceding clause(s) of any one or more of Examples 15-16, wherein the second surface defines a first end of the shroud and the third surface defines a second end of the shroud, the second end opposite the first end.

Example 18 includes any preceding clause(s) of any one or more of Examples 15-17, further including a mount covered by the shroud, the mount to support the blower, the mount including at least one opening defined therein, the blower to intake the air from the plurality of second openings via the at least one opening defined in the mount.

Example 19 includes any preceding clause(s) of any one or more of Examples 15-18, wherein the backplate includes a plurality of third openings defined therein, the blower to intake air via the plurality of the third openings.

Example 20 includes any preceding clause(s) of any one or more of Examples 15-19, wherein a shape of the first opening is different than a shape of respective ones of the plurality of second openings.

Example 21 includes a workstation comprising a chassis having a first sidewall, the first sidewall including a first vent; a first electronic component in the chassis; a shroud including a second vent defined in a first surface of the shroud, the first surface of the shroud facing the first vent; a backplate coupled to the shroud to form a housing for the first electronic component; and a blower, an air intake flow path for the blower passing through the first vent and the second vent.

Example 22 includes any preceding clause(s) of Example 21, wherein the backplate includes a third vent defined therein and further including a second electronic component in the chassis, the backplate facing the second electronic component.

Example 23 includes any preceding clause(s) of any one or more of Examples 21-22, wherein the shroud includes a blower inlet defined in a second surface of the shroud, the second surface of the shroud facing a second sidewall of the chassis.

Example 24 includes any preceding clause(s) of any one or more of Examples 21-23, wherein the first electronic component includes a surface to support the blower, the surface including an opening defined therein, the air intake flow path passing through the opening in the surface.

Example 25 includes a method comprising forming an inlet in a first surface of a shroud; forming an intake vent in a second surface of the shroud; coupling the shroud to a backplate to form a housing for an electronic component, a blower of the electronic component between the shroud and the backplate and in fluid communication with the inlet and the intake vent to receive air via the inlet and the intake vent; and coupling the housing to chassis, the second surface facing a grille of the chassis.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

The status of the claims:

1. An apparatus comprising:
a shroud having an inlet defined in a first surface, an intake vent defined in a second surface, and an outlet defined in a third surface;
a backplate coupled to the shroud to form a housing; and
a blower in the housing, the blower to receive air via the inlet and the intake vent and to direct the air toward the outlet.

2. The apparatus of claim 1, further including a mount in the housing to support the blower, the mount including an opening defined therein, the opening in fluid communication with the intake vent.

3. The apparatus of claim 2, wherein a gap is defined between the backplate and the mount, an airflow path defined from the intake vent to the blower via the gap.

4. The apparatus of claim 2, wherein the intake vent is a first intake vent and the backplate includes a second intake vent defined therein.

5. The apparatus of claim 1, wherein the intake vent includes a plurality of openings defined in the second surface of the shroud.

6. The apparatus of claim 1, wherein the second surface is orthogonal to the first surface.

7. The apparatus of claim 1, wherein the first surface is opposite the backplate.

8. A system comprising:
a chassis having a grille defining an exterior surface thereof;
an electronic component;
a blower; and
a housing in the chassis, the electronic component and the blower in housing, the housing including:
a shroud having an inlet for the blower and an intake vent; and
a backplate coupled to the shroud, the backplate spaced apart from the blower to define a gap between the backplate and the blower, an airflow path to the blower defined by the grille, the intake vent, and the gap.

9. The system of claim 8, wherein a first surface of the shroud including the intake vent faces the grille of the chassis.

10. The system of claim 9, wherein a second surface of the shroud includes an outlet, the second surface opposite the first surface.

11. The system of claim 8, wherein the housing includes a mount to support the blower, the mount including an opening defined therein, the opening in fluid communication with the gap.

12. The system of claim 8, wherein the intake vent is a first intake vent and the backplate includes a second intake vent defined therein, air entering the second intake vent to pass through the gap toward the blower.

13. The system of claim 8, wherein the electronic component is a graphics processing unit.

14. The system of claim 8, wherein the electronic component is a central processing unit.

15. A graphics card comprising:
a shroud, a first surface of the shroud having a first opening defined therein, a second surface of the shroud having a plurality of second openings defined therein;
a graphics processing unit covered by the shroud;
a blower covered by the shroud, the blower to intake air via the first opening and the plurality of second openings; and
a backplate coupled to the shroud, the backplate opposite the first surface.

16. The graphics card of claim 15, further including a heatsink covered by the shroud, the shroud including a third surface having a plurality of third openings defined therein, wherein the second surface and the blower are on a first side of the heatsink and the third surface is on a second side of the heatsink opposite the first side, the air to exit via the plurality of third openings.

17. The graphics card of claim 16, wherein the second surface defines a first end of the shroud and the third surface defines a second end of the shroud, the second end opposite the first end.

18. The graphics card of claim 15, further including a mount covered by the shroud, the mount to support the blower, the mount including at least one opening defined therein, the blower to intake the air from the plurality of second openings via the at least one opening defined in the mount.

19. The graphics card of claim 15, wherein the backplate includes a plurality of third openings defined therein, the blower to intake air via the plurality of the third openings.

20. The graphics card of claim 17, wherein a shape of the first opening is different than a shape of respective ones of the plurality of second openings.

21.-25. (canceled)
